(19) United States
(12) Patent Application Publication
(10) Pub. No.: US 2008/0029153 A1
(43) Pub. Date: Feb. 7, 2008

(54) Portable power supply

(76) Inventor: Erez Margalit, Pasadena, CA (US)

Correspondence Address: BERGMAN & SONG, LLP, P.O. BOX 400198, CAMBRIDGE, MA, 02140, US

(21) Appl. No.: 11/890,547

(22) Filed: Aug. 4, 2007

Related U.S. Application Data
(60) Provisional application No. 60/835,468, filed on Aug. 4, 2006.

(51) Int. Cl. H01L 31/04; H02J 1/00; H02J 7/35

(52) U.S. Cl. 136/252; 320/101; 323/234

(57) ABSTRACT

Disclosed is an electrical power converter circuit including a photovoltaic cell and a power supply adapted to control a low power output of the photovoltaic cell. The power supply includes an input switch, an over-voltage detector, an under voltage detector, a rechargeable battery, a DC to DC converter circuit, an output capacitor, a delay element and an output switch. An item of luggage is adapted to support and carry the photovoltaic cell, power supply, and optional ancillary equipment.

### CROSS-REFERENCE TO RELATED APPLICATIONS

The present application claims the benefit of U.S. provisional patent application No. 60/835,468 filed on Aug. 4, 2006, the disclosure of which is herewith incorporated by reference in its entirety.

### FIELD OF THE INVENTION

The present invention relates to power supplies, and more particularly to portable power supplies.

### BACKGROUND

Small electronic portable appliances such as cellular phones, compact entertainment devices, hand-held “palm” computers, GPS navigation devices, and small wireless communication equipment have become extremely popular with people of all ages, gender, and location.

All of these devices use electrical power to operate. As portable devices they are not connected to power utility outlets, but instead use batteries as a power source. An ever increasing percentage of these appliances use rechargeable batteries. Unlike regular batteries which are replaced with new batteries when they run out of power, while the used batteries are disposed of, rechargeable batteries can be recharged from an external power source, again and again, and need not be replaced.

Recharging of portable appliances is typically done by connecting such portable appliances to a power supply which is connected in turn to a residential power utility, thus limiting portability, at least temporarily.

### SUMMARY

To make such small portable appliances more portable and usable everywhere without a need to recharge the batteries of these portable appliances from the power utilities or automotive power outlets, the inventor is harnessing the power of ambient light including, in particular, the sun.

In daily life many people carry handbags and backpacks in which they store and carry personal items such as money, documents, books, cosmetics items, and small portable electronic appliances.

According to this invention, a personal backpack, duffel bags, handbag, or luggage of any description, is fitted with a photovoltaic cell. The term photovoltaic cell is used broadly to encompass monocrystalline, polycrystalline and amorphous photovoltaic cells including cells having silicon material therein, as well as cells including other materials such as, for example, III-V semiconductor materials. Also included within the scope of the invention is a device including an organic polymer photovoltaic device, and a substantially flexible photovoltaic device. In addition, the term photovoltaic cell is used broadly to encompass other solar cells and other energy conversion devices.

The photovoltaic cell is applied to convert electromagnetic energy, such as visible light, for example, into electrical power to operate a power supply and/or battery charging apparatus capable of, for example, charging the batteries or other energy storage device of portable electronic appliances. This enables such a backpack or handbag to simultaneously charge and use the small portable appliances while carried around wherever the user carries the backpack, handbag, or other luggage.

These and other advantages and features of the invention will be more readily understood in relation to the following detailed description of the invention, which is provided in conjunction with the accompanying drawings.

### BRIEF DESCRIPTION OF THE DRAWINGS

FIG. 1 shows, in block diagram form, a portable container including a photovoltaic power supply according to one embodiment of the invention;

FIG. 2 shows, in block diagram form, a photovoltaic power supply according to one embodiment of the invention;

FIG. 3 shows, in schematic perspective view, a photovoltaic power supply and luggage combination according to one embodiment of the invention;

FIGS. 4A-4B show, in perspective view, an exemplary embodiment of the invention including an attaché case;

FIG. 5 shows, in perspective view, an exemplary embodiment of the invention including a duffel bag;

FIG. 6 shows, in perspective view, an exemplary embodiment of the invention including a suitcase; and

FIG. 7 shows, in perspective view, an exemplary embodiment of the invention including a purse.

### DESCRIPTION

The following description is provided to enable any person skilled in the art to make and use the disclosed inventions and sets forth the best modes presently contemplated by the inventor of carrying out his invention. In the following description, for purposes of explanation, numerous specific details are set forth in order to provide a thorough understanding of the present invention. It will be apparent to one skilled in the art, however, that the present invention may be practiced without these specific details.

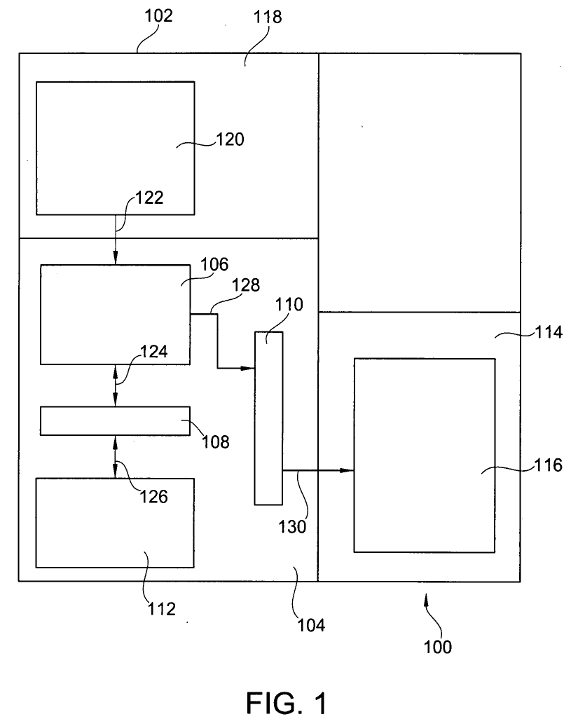

FIG. 1 shows, in block diagram form, a luggage system 100 according to one embodiment of the invention. The luggage system 100 includes a portable container 102 in one of a wide variety of possible physical arrangements. As will be discussed additional detail below, these arrangements include, for example, a briefcase, a catalog case, a duffel bag, a backpack, a rucksack, a suitcase, a suit bag, a purse, handbag, a grip, a medical bag, a portfolio, an attaché case, a book bag, a toolbox, a tackle box, a tool bag, a kitbag, and any other special-purpose and general purpose container, as is known in the art.

In one embodiment, as illustrated, the portable container 102 includes a first compartment 104. The first compartment 104 is adapted to receive an electrical power supply device therewithin. In the illustrated embodiment, the electrical power supply device includes a power converter 106 first 108 and second 110 electrical coupling devices, and an optional power storage device 112. For purposes of the present description, the term power converter 106 is intended to include variously, an AC power supply, an inverter, a DC power supply, a battery charger, and a DC to DC voltage converter. In the illustrated embodiment, the optional power storage device 112 is illustrated as a device including an electro-chemical battery, however, in other embodiments, the optional power storage device 112 is implemented as a device including a capacitor storage device, an electro-mechanical power storage device such as, for example, a spring or a flywheel, and an electro-chemical fuel cell, among others.

In the embodiment of FIG. 1, the portable container 102 includes a second compartment 114. The second compartment 114 is adapted to receive an electrical device 116 including, but not limited to, a portable electronic device such as, for example, a cellular telephone, video recording device, a video playback device, an audio recording device, a still-image recording device, a still-image display device, an audio playback device, a radio signal receiving device, a global positioning system device, a transportable medical device including, for example, a medical stimulating device or a medical sensing device, a scientific instrument, a computer, a calculator, and an emergency locating device, among others.

Also shown in the FIG. 1 embodiment is a support region 118 for an energy capture device. In various embodiments, the support region includes a third compartment. In another embodiment the support region 118 includes an external surface of the portable container 102. In one embodiment, the energy capture device is a photovoltaic cell 120. The support region 118 is adapted to support the photovoltaic cell 120 in an orientation for receiving incident light.

In the illustrated embodiment, an electrical conductor 122 is adapted to couple an electrical output of the photovoltaic cell 120 to an electrical input of the power converter 106. The power converter 106 is coupled through further electrical conductors 124, 126 and electrical coupling device 108 to power storage device 112. The power converter device 106 is also adapted to be coupled through still further electrical conductors 128, 130 and electrical coupling device 110 to electrical device 116 for purposes of supplying electrical energy to device 116.

As further illustrated in the FIG. 1 embodiment, the portable container 102 includes a further compartment 132. The further compartment is adapted to contain ancillary equipment of any general or specific nature according to the particular embodiment of the invention. Accordingly, and purely by way of example, further compartment 132 may be adapted to contain clothing, papers, books, medical equipment, medical consumables, computers, camping gear, sports equipment, fishing equipment, and any other substantially portable equipment.

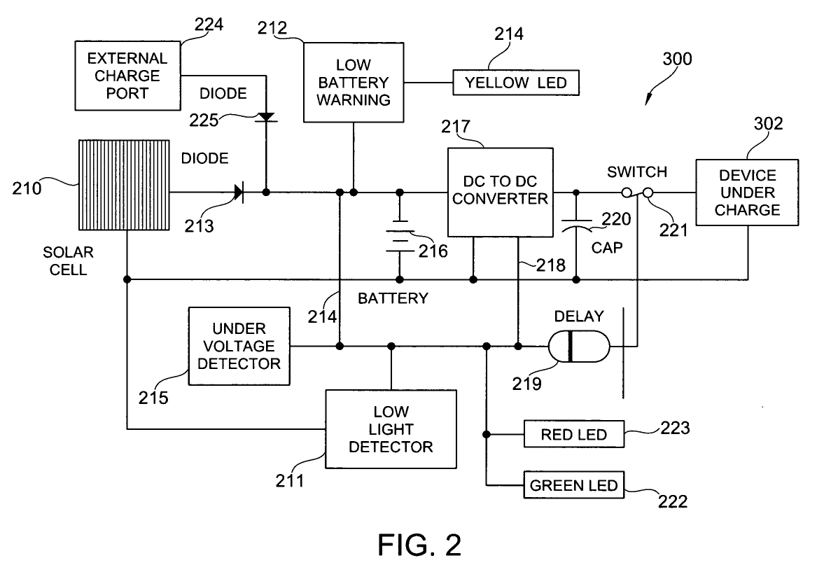

FIG. 2 shows a further embodiment of the invention including a device for the conversion of electromagnetic energy to electrical energy such as, for example, a photovoltaic cell 210 which is electrically coupled to a DC to DC converter 217 and a rechargeable battery 216 via a diode 213. When the photovoltaic cell 210 is exposed to light it generates an electrical current.

The light source may be the sun, or any other electromagnetic energy source of appropriate wavelength and intensity. As a result of exposure to light, the voltage at the positive output pin of the photovoltaic cell 210 increases above the voltage across the battery 216. Under these conditions, a current generated in the photovoltaic cell 210 can flow through the diode 213 to charge the battery 216.

A voltage across the battery 216 is a property of the chemistry of the battery and the charge in the battery. The chemistry determines the nominal voltage on the battery while the charge in the battery can change the voltage across the battery by as much as 20%. For example, the typical nominal voltage on a Nickel Cadmium battery is 1.2V, but the actual battery voltage may be as low as 1.15V when the battery is discharged, and as high as 1.4V when such battery is fully charged.

When a voltage higher than the nominal voltage of a battery is desired, two or more batteries can be connected in series, to yield an overall voltage which is the nominal voltage multiplied by the number of batteries connected in series. This is a disadvantage as other voltages are not easily obtainable.

To adapt the charger to the requirements of various different portable electronic appliances, a DC to DC converter 217 connects to the battery 216. The DC voltage output of the DC to DC converter 217 can be set to any value, lower, equal, or higher than the voltage across the battery 216, and thus may be adjusted, automatically or manually, to the specific requirements of different portable electronic appliances 302.

With the foregoing in mind, according to one embodiment of the invention, the DC to DC adapter is adapted to receive a communication signal from a device under charge. The communication signal indicates an appropriate voltage and current setting for the DC to DC adapter in relation to the particular device under charge.

A charger 300 is designed to continuously charge the portable electronic appliances 302 connected to the charger 300. However, charging the appliance 302 when intensity of the light to which the photovoltaic cell 210 is exposed is too low, may deplete the battery 216 of its charge, causing improper operation of the charger 300. Two circuits are used here to prevent the battery from being over discharged. One is such that when the photovoltaic cell 210 output is insufficient to charge the battery 216, the low light detection 211 comparator will control the DC to DC converter 217 to it's OFF state, and after a short delay via the delay element 219, will control the output switch 221 to the OFF state, which will disconnect the charge current to the external appliance 302.

Consequently, when the light onto the solar panel 210 is of sufficient intensity to overcome the predetermined set-point voltage at the comparator input 211, the comparator 211 will change its state, and the DC to DC converter 217 and the output switch 221 will again be controlled to the ON state, enabling the charge current to the external appliance 302. A green LED 222 will serve to indicate that the charger 300 is currently capable of charging an external appliance 302.

The other circuit section consists of a battery low voltage detector 215. This circuit monitors a voltage at the battery 216. If the voltage across the battery 216 falls below the preset low level threshold voltage, in this case, approximately 2.4 volts, the detector/comparator 215 will control the DC to DC converter 217, and the output switch 221 to the OFF state, subsequently disconnecting the external appliance 302. A red LED 223, connected to the detector 15, when illuminated, will serve to indicate that the charger 300 is not currently capable of charging an external appliance 302.

When the battery voltage is again of sufficient level to reset the state of the comparator 215 (about 2.6 volts, in the illustrated embodiment) the output of the comparator 215 will control the DC to DC converter 217 to it's ON state, and after a short delay, via the delay element 19 will also control the output switch 221 to it's ON state, therefore allowing the charger to charge the external appliance 302. Consequently, the green LED 222, connected to the output of the detector 215, will illuminate to indicate that the charger 300 is now capable of charging an external appliance 302.

The low battery warning circuit 212 alerts the user as to the state of charge of the battery 216. When the voltage of battery 216 falls below a predetermined set point, the low battery detection circuit 212 will change state, and will cause to illuminate a yellow LED 214. When illuminated, this will serve to alert the user as to the approaching discharged condition of the battery 216, and the user can then take the necessary action to recharge the battery 216.

When the photovoltaic cell 210 is exposed to a sufficient intensity of light, the voltage generated by the photovoltaic cell 210 is no longer lower than that of the battery 216, and the under voltage detector 215 turns ON the DC to DC converter 217. The DC to DC converter 217 requires some time to start-up and build-up the output voltage required for the portable electronic appliance 302. The delay element 219 causes a delay in the turn ON of the switch 221, enabling the DC to DC converter 217 to initialize without a load, and then connects it to the portable electronic appliance 302 only after the voltage generated by the DC to DC converter 217 is stabilized. Consequently, the green LED 222, connected to the output of the detector 215, will illuminate to indicate that the charger 300 is now capable of charging an external appliance 302.

External charge port 224 allows for supplemental charging of charger 300 from other sources when sunlight is unavailable, such as at night or when indoors under low light conditions. In one embodiment, the charge port 224 consists of a USB mini-B connector that is compatible with industry standard USB format. Using an appropriate cable, the charger 300 can be charged via any personal computer that is equipped with a USB port. Current from the USB source is coupled to the battery 216 through diode 225.

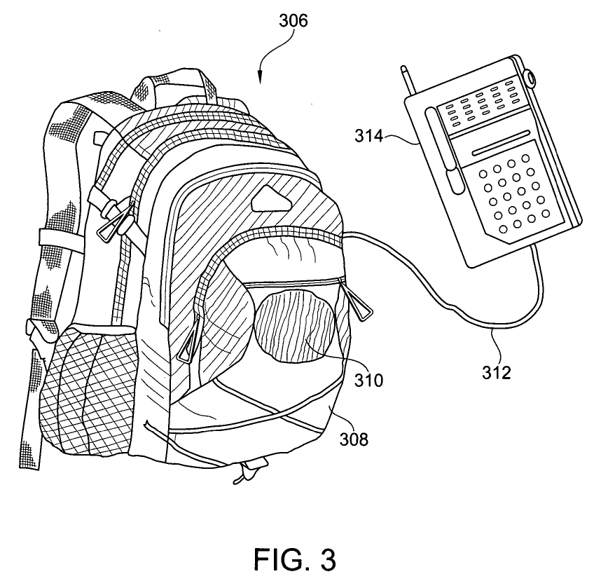

FIG. 3 shows a backpack including a portable photovoltaic power supply according to one embodiment of the invention. In the illustrated embodiment, the backpack 306 includes an external surface 308. A photovoltaic cell 310 is substantially fixedly coupled to external surface 308. The photovoltaic cell 310 is arranged to receive light from an external light source, such as the Sun, whenever such a light source is available. According to one embodiment of the invention, the photovoltaic cell 310 is coupled to the external surface 308 by means of an adhesive. In another embodiment of the invention, photovoltaic cell 310 is coupled to the external surface 308 by means of a mechanical fastener.

According to one exemplary embodiment of the invention, a power supply device, such as that illustrated in FIG. 2, is disposed within the backpack 306. The power supply device is elected to coupled to the photovoltaic cell 310 to receive electrical energy to therefrom. A power output port of the power supply device is coupled through a cable 312, including an electrical conductor, to a power input port of a portable electrical appliance.

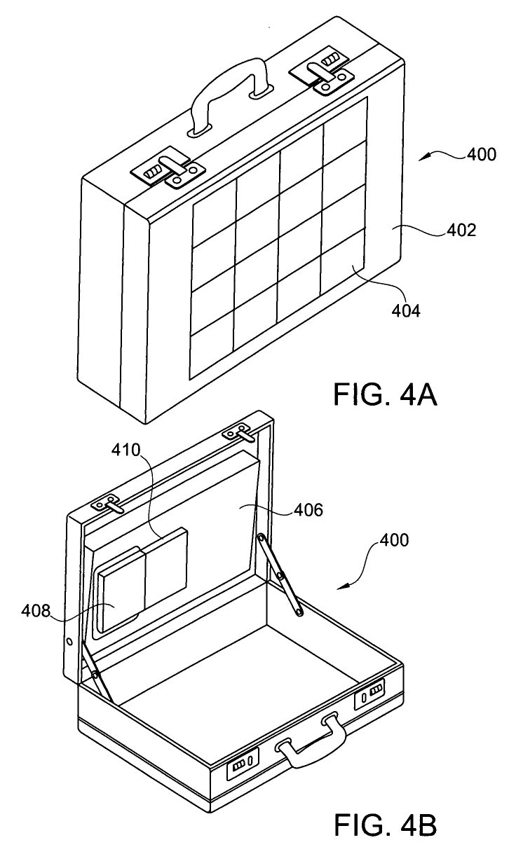

FIG. 4A and FIG. 4B show an attaché case 400 according to a further embodiment of the invention. As illustrated, the attaché case 400 includes a substantially planar external surface 402. As illustrated, one or more photovoltaic cells 404 are disposed on the external surface 402. The one or more photovoltaic cells 404 are, in various embodiments, permanently or remotely coupled to external surface 402. In one exemplary embodiment, an adhesive is used to substantially permanently join the photovoltaic cell 404 to surface 402. In another exemplary embodiment, a mechanical faster is used to permanently or temporarily join the photovoltaic cell 404 to surface 402. In still another embodiment, photovoltaic cell 404 includes a removable module adapted to be removably and replaceably coupled to surface 402.

FIG. 4B shows a further view of the attaché case embodiment 400. As shown in FIG. 4B, an internal surface 406 of the attaché case supports an electronic power supply device 408. The attaché case 400 also includes a specialized compartment 410 adapted to receive a portable electronic appliance therewithin.

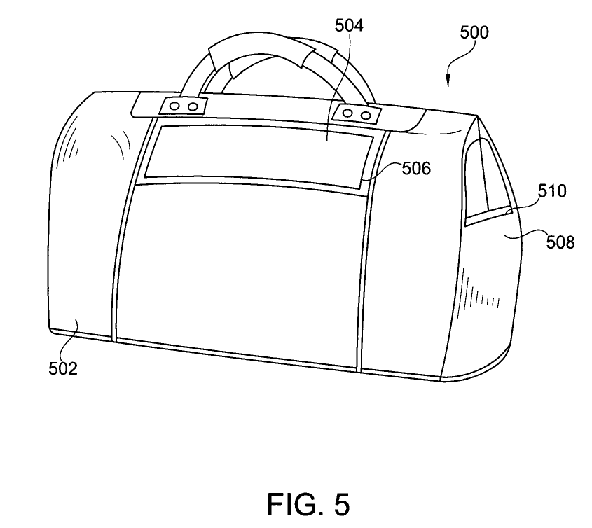

FIG. 5 shows still another exemplary embodiment of the invention. In FIG. 5, a duffel bag and/or medical bag 500 is shown to include an external surface 502. A photovoltaic cell module 504 is shown supported by a region 506 of external surface 502. In one embodiment of the invention, region 506 includes a curved region. According to one embodiment of the invention, photovoltaic cell module 504 includes a substantially flexible and/or curved photovoltaic cell portion. In the illustrated embodiment, photovoltaic cell module 504 substantially conforms to a shape of the surface region 506.

In another aspect of the invention, duffel bag 500 includes an externally accessible compartment 508. An aperture 510 of the externally accessible compartment 508 is adapted to receive a portable electronic appliance into the compartment 508 without otherwise opening the duffel bag 500. Such an externally accessible compartment 508 is particularly and surprisingly useful where the duffel bag 500 is employed as a medical bag and where the portable electronic appliance is desirably highly available for urgent application.

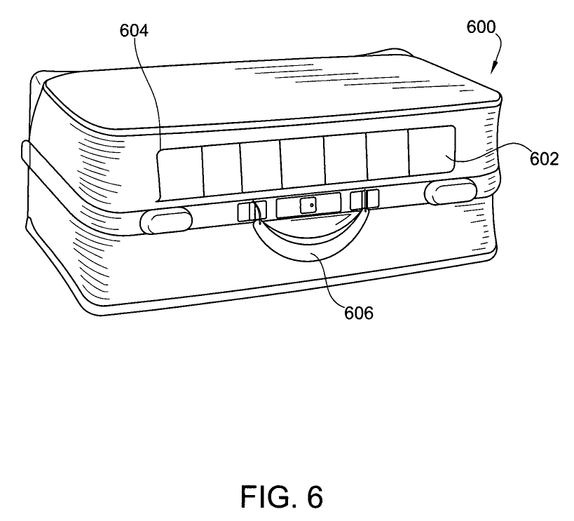

FIG. 6 shows still another embodiment of the invention including a suitcase 600 having a photovoltaic module 602. In the illustrated embodiments, the photovoltaic module is applied to a surface region 604 adjacent to a handle 606. The surface region 604 is likely to be oriented upwardly during a time interval when the suitcase 600 is being carried, so that during that time interval, the photovoltaic module 602 is likely to be oriented towards an overhead light source such as, for example, the Sun.

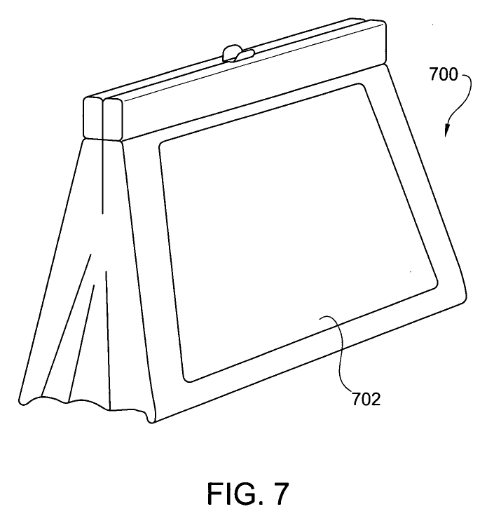

FIG. 7 shows an embodiment of the invention in which a purse 700 includes a photovoltaic module 702. The photovoltaic module 702 provides power for operation of a portable electronic appliance as described above, for example. In addition to its power-supplying aspects, the photovoltaic module provides the further functions of beautifying the purse 700 and lending prestige to its owner.

While the exemplary embodiments described above have been chosen primarily from the field of portable electric devices, one of skill in the art will appreciate that the principles of the invention are equally well applied, and that the benefits of the present invention are equally well realized in a wide variety of other power supply systems including, for example, remote unmanned installation power supply systems. Further, while the invention has been described in detail in connection with the presently preferred embodiments, it should be readily understood that the invention is not limited to such disclosed embodiments. Rather, the invention can be modified to incorporate any number of variations, alterations, substitutions, or equivalent arrangements not heretofore described, but which are commensurate with the spirit and scope of the invention. Accordingly, the invention is not to be seen as limited by the foregoing description, but is only limited by the scope of the appended claims.

1. A Photovoltaic cell powered electrical power source for a portable electronic appliance comprising:
a photovoltaic cell;
a power converter and conditioner circuit; and
a luggage article, said photovoltaic cell being adapted to be coupled to said luggage article.

2. A Photovoltaic cell powered electrical power source as in claim 1 wherein said photovoltaic cell is mounted on an outside surface of said luggage article.

3. A Photovoltaic cell powered electrical power source as in claim 1 wherein said power converter and conditioner circuit is adapted to receive a time-varying current generated by said photovoltaic cell and output a substantially constant predetermined voltage.

4. A Photovoltaic cell powered electrical power source as in claim 1, wherein said power converter and conditioner circuit is adapted to be automatically adjusted to respective specific power requirements of a plurality of portable electronic appliances capable of being powered by said power source.

5. A Photovoltaic cell powered electrical power source as in claim 1 wherein electrical power generated by said electrical power source is adapted to charge a rechargeable battery of a portable electronic device.

6. A Photovoltaic cell powered electrical power source as in claim 1 wherein said luggage article is adapted to be carried by at least one of straps and handles.

7. A Photovoltaic cell powered electrical power source as in claim 1 wherein the Photovoltaic cell powered electrical power source is adapted to power a portable electronic entertainment device.

8. A Photovoltaic cell powered electrical power source as in claim 1 wherein the Photovoltaic cell powered electrical power source is adapted to power a portable electronic communication device.

9. A Photovoltaic cell powered electrical power source as in claim 1 wherein the Photovoltaic cell powered electrical power source is adapted to power a portable electronic navigational aid device.

10. A Photovoltaic cell powered electrical power source for a portable electronic appliance comprising:
a photovoltaic cell;
a power converter and conditioner circuit; and
a garment article.

11. A Photovoltaic cell powered electrical power source as in claim 10 wherein said photovoltaic cell is adapted to be coupled to an outside surface of said garment article.

12. A Photovoltaic cell powered electrical power source as in claim 10 wherein said power converter and conditioner circuit is adapted to receive a time-varying current produced by said photovoltaic cell and output a substantially constant predetermined voltage.

13. A Photovoltaic cell powered electrical power source as in claim 10 wherein said power converter and conditioner circuit is adapted to be automatically adjusted to respective specific power requirements of a plurality of portable electronic appliances capable of being powered by said power source.

14. A Photovoltaic cell powered electrical power source as in claim 10 wherein electrical power generated by said electrical power source is adapted to charge a rechargeable battery of a portable electronic device.

15. A Photovoltaic cell powered electrical power source as in claim 10 wherein the garment article is adapted to be donned over a human body.

16. A Photovoltaic cell powered electrical power source as in claim 10 wherein the Photovoltaic cell powered electrical power source is adapted to power a portable electronic entertainment device.

17. A Photovoltaic cell powered electrical power source as in claim 10 wherein the Photovoltaic cell powered electrical power source is adapted to power a portable electronic communication device.

18. A Photovoltaic cell powered electrical power source as in claim 10 wherein the Photovoltaic cell powered electrical power source is adapted to power a portable electronic navigational aid device.

19. A Photovoltaic cell powered electrical power converter circuit comprising:
a photovoltaic cell;
an under voltage detector;
a rechargeable battery;
a DC to DC converter circuit;
a delay element; and
an output switch.

20. A Photovoltaic cell powered electrical power converter circuit as in claim 19 wherein an output voltage of said DC to DC converter is substantially independent of a voltage at an input of the DC to DC converter.

21. A Photovoltaic cell powered electrical power converter circuit as in claim 19 wherein an output voltage of said DC to DC converter can be at least one of higher, lower and equal to a voltage at an input of said DC to DC converter.

22. A Photovoltaic cell powered electrical power converter circuit as in claim 19 wherein an output voltage of said DC to DC converter is adapted to be automatically adjusted to respective specific voltage requirements of a plurality of portable electronic appliances capable of being powered by said photovoltaic cell powered electrical power converter.

23. A Photovoltaic cell powered electrical power converter circuit as in claim 19 further comprising:
an under voltage detector, said under voltage detector being adapted to monitor a voltage produced by said photovoltaic cell, said under voltage detector being adapted to produce an output signal, said output signal being adapted to control an operation of said DC to DC converter circuit.

24. A Photovoltaic cell powered electrical power converter circuit as in claim 23 wherein said output signal is adapted to turn said DC to DC converter circuit OFF when insufficient power is generated by said photovoltaic cell and to turn said DC to DC converter circuit ON when sufficient power is generated by the photovoltaic cell.

25. A Photovoltaic cell powered electrical power converter circuit as in claim 19 wherein a delay element is coupled between an output of the said DC to DC converter circuit and a control input of said output switch.

26. A Photovoltaic cell powered electrical power converter circuit as in claim 19 wherein said output switch is adapted to be coupled between an output of said DC to DC converter circuit and a power input of a portable electronic appliance, said appliance being coupled to receive power produced by said photovoltaic cell.

27. A Photovoltaic cell powered electrical power converter circuit as in claim 19 wherein said delay element is adapted to cause said output switch to be turned ON some first delay time after said DC to DC converter circuit is turned ON and turned OFF some second delay time after said DC to DC converter circuit is turned OFF.

28. A Photovoltaic cell powered electrical power converter circuit as in claim 27 wherein said first delay time is equal to said second delay time.

29. A Photovoltaic cell powered electrical power converter circuit as in claim 19 further comprising a rechargeable battery, said rechargeable battery being adapted to be coupled to an input of said DC to DC converter circuit, said battery being adapted to power said DC to DC converter circuit during a time interval when said photovoltaic cell does not generate sufficient power to power said DC to DC converter circuit.
